(19) United States
(12) Patent Application Publication
(10) Pub. No.: US 2002/0149012 A1
(43) Pub. Date: Oct. 17, 2002

(54) Semiconductor device

(75) Inventor: Yusuke Kawase, Hyogo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 09/948,610

(22) Filed: Sep. 10, 2001

(30) Foreign Application Priority Data
Apr. 17, 2001 (JP) 2001-117821

(51) Int. Cl. H01L 23/58

(52) U.S. Cl. 257/48; 257/774

(57) ABSTRACT

A semiconductor device has: a semiconductor substrate as a base layer having a main surface; a plurality of wiring swellings formed so as to be linearly swollen on the main surface; and a plurality of plugs made of a conductive material formed so as to bury a part of a recess formed by being sandwiched by wiring swellings. Wiring swelling includes a wiring layer, an on-wiring stopper film as a wiring layer top face protective layer formed so as to cover the top face of wiring layer, and a side wall spacer covering a side face of wiring layer and a side face of on-wiring stopper film. The level of the top face of wiring swelling and that of the top face of plug are almost the same with respect to the main surface as a reference.

### BACKGROUND OF THE INVENTION

1. Field of the Invention

The present invention relates to a semiconductor device having plug-type contact holes formed in a self aligning manner and a method of fabricating the same.

2. Description of the Background Art

As an LSI (Large Scale Integrated circuit) becomes finer and its packing density increases, positioning of extremely high accuracy is required for overlaying a circuit pattern only by photolithography. Under such circumstances, self-aligned contact etching lessens the required overlay accuracy. Since the required overlay accuracy is lessened by the self-aligned contact etching, design with the aim of achieving a finer device can be realized. The technique related to the self-aligned contact etching is therefore important in development of a semiconductor device.

Referring to FIGS. 34 to 45, a method of fabricating a semiconductor device in accordance with the conventional technique will be described.

By a known technique, an isolated insulating film 1 is formed on the surface of a semiconductor substrate 2 except for active regions 21. On the top face of semiconductor substrate 2, a wiring layer 4 having an on-wiring insulating film 3 is formed by a known technique. On-wiring insulating layer 3 is an insulating film intended to protect wiring layer 4 at the time of performing self-aligned contact hole etching. FIG. 34 is a plan view showing a resultant of the process. FIG. 35 is a cross section taken on line XXXV-XXXV. As shown in FIG. 36, by CVD (Chemical Vapor Deposition) or the like, a nitride film 25 is formed on the top face so as to cover wiring layer 4 and on-wiring insulating film 3. Nitride film 25 is to serve as a side wall spacer 5 (refer to FIG. 42) functioning as a stopper film when the self-aligned contact etching is performed.

As shown in FIG. 37, an insulating interlayer 6 is formed so as to cover nitride film 25 by CVD or the like, and its top face is planarized by CMP (Chemical Mechanical Polishing) or entire-face etching.

Further, a resist film 9 is formed on insulating interlayer 6. When it is seen from above, the entire substrate is covered with resist film 9. As shown in FIG. 38, a photolithography pattern 7 is disposed in the position of each active area 21 and exposure is performed. As a result, resist film 9 is removed from only the positions in which contact holes are desired to be opened. Anisotropic dry etching is performed by using resist film 9 as a mask to remove insulating interlayer 6. As a result, as shown in FIG. 39, contact holes 110 are formed where plugs are desired to be provided. In contact holes 110, since insulating interlayer 6 is removed, nitride film 25 is exposed. FIG. 40 is a cross section taken along line XL-XL of FIG. 39.

As shown in FIG. 41, residual resist film 9 is removed. In a state where there is no resist film 9, anisotropic dry etching is performed on the entire face. As shown in FIG. 42, a part of nitride film 25 is removed to expose active area 21 on the bottom of contact hole 110. Since contact holes 110 are etched in a self-aligned manner, high accuracy control of positioning holes is unnecessary. After exposing active area 21, nitride film 25 partially remains as side wall spacers 5. Since a part of insulating interlayer 6 is also etched by the anisotropic dry etching, as shown in FIG. 42, the thickness of insulating interlayer 6 is slightly reduced. FIG. 43 is a plan view showing the state at this stage. FIG. 42 is a cross section taken along line XLII-XLII of FIG. 43. As shown in FIGS. 42 and 43, side wall spacer 5 and active area 21 of semiconductor substrate 2 are exposed on the inside of contact hole 110.

By CVD or the like, polysilicon or the like is applied so as to cover the entire top face. The polysilicon is the material of plugs 111 to be formed. The surface is planarized by CMP, etch-back, or the like, thereby forming plugs 111 as shown in FIG. 44. As a result, plug 111 is electrically connected to active area 21 exposed on the bottom of contact hole 110.

As shown in FIG. 45, a new insulating interlayer 106 is formed. On the top face of insulating interlayer 106, a next wiring layer can be formed.

By repeating such a process, a semiconductor device in which a plurality of wiring layers are stacked and connected via plugs in the vertical direction is obtained.

The semiconductor device according to the conventional technique as described above has, however, three problems which will be described hereinbelow.

First Problem

A first problem is short-circuiting caused by deterioration in burying property of the insulating interlayer. As devices are becoming finer in recent years, the interval between neighboring wiring layers 4 in the same layer is becoming narrower. There is also a case such that the film thickness of on-wiring insulating film 3 and nitride film 25 varies. Due to the factors, there is a problem such that the burying property of burying a material between wiring layers 4 deteriorates even when insulating interlayer 6 having high covering properties is used. Concrete deterioration in burying property is, for example, as shown in FIG. 46, the recesses cannot be buried completely due to cavities 33 created in insulating interlayer 6 grown on the uneven surface of nitride film 25. Since the cavity 33 is formed so as to extend in the direction perpendicular to the drawing sheet of FIG. 46, when contact holes 110 (refer to FIG. 40) are filled with the material of plugs, the material of plugs may enter the cavities 33. In this case, there is a problem such that one of plugs 111 and the other plug 111 neighboring to the one of plugs 111 in the direction perpendicular to the drawing sheet of FIG. 46 are short-circuited via the plug material in the cavity 33.

Second Problem

A second problem is insufficient insulation. As shown in FIGS. 38 to 43, since the etching process is performed twice to form the contact holes 110, the amount of removing nitride film 25 by etching tends to be large. If nitride film 25 is removed excessively, there is the case such that nitride film 25 becomes too thin as side wall spacer 5 to protect wiring layer 4 from plug 111 on the side by insulation. When the film thickness of on-wiring insulating film 3, side-wall spacer 5, and insulating interlayer 6 and the etching rate at the time of forming the connection hole 110 vary, the accuracy of the shape obtained finally deteriorates cumulatively. Due to the factors, a case where the insulation on wiring layer 4 is insufficient may occur.

Third Problem

A third problem is an increase in thickness. In the case of fabricating the device in accordance with the conventional technique, as shown in FIG. 45, the layers including plug 11 formed by the series of processes become thick. The thickness of a product finally obtained by repeatedly forming such layers increases more conspicuously. The increase in thickness disturbs reduction in size of a product and makes it difficult to carry out wiring through the layers.

An object of the invention is to provide a semiconductor device realized while solving the three problems and a method of fabricating the same.

### SUMMARY OF THE INVENTION

In order to achieve the object, according to an aspect of the invention, a semiconductor device includes: a base layer having a main surface; a plurality of wiring swellings formed so as to be linearly swollen on the main surface; and a plurality of plugs made of a conductive material formed so as to bury a part of a recess in plan view, the recess formed on the main surface by being sandwiched by the wiring swellings. The wiring swelling includes a wiring layer, a wiring layer top face protective layer formed so as to cover the top face of the wiring layer, and a side wall spacer covering a side face of the wiring layer and a side face of the wiring layer top face protective layer. The level of the top face of the wiring swelling and that of the top face of the plug being almost the same with respect to the main surface as a reference. With the configuration, a fabrication method of forming a plug first and forming the insulating interlayer can be employed. Thus, a problem of short circuit between plugs caused by a cavity conventionally created in the insulating interlayer can be solved. Since the number of times the side wall spacer is subjected to etching decreases, insulation of the wiring layer by the side wall spacer can be performed more reliably. Further, the height of the plug is almost the same as that of the wiring swelling, so that the thickness of the whole can be reduced.

In the invention, preferably, a plug arrangement area in which at least three plugs are arranged in the direction intersecting the wiring swelling is provided. In the plug arrangement area, the level of the top face of the wiring swelling in a portion sandwiched by the plugs is higher than that of the top face of the other portion in the wiring swelling. By adopting the configuration, the material of the plug is formed first on the entire face and a portion to become a plug and the other portion can be separately formed by using a photolithographic pattern covering the plug arrangement area. Thus, the fabrication is facilitated and the device can be fabricated with high accuracy.

In the invention, preferably, a plug arrangement area in which at least four plugs are arranged in the direction intersecting the wiring swelling is provided. The base layer is a semiconductor substrate partly having an isolated insulating film in the main surface, and a plug directly connected only to the isolated insulating film in the base layer is included in the plug arrangement area. Alternately, in the invention, preferably, a plug arrangement area in which at least four plugs are arranged in the direction intersecting the wiring swelling is provided. The wiring swelling includes an insulating interlayer under the wiring layer, the base layer includes a conductive area and a non-conductive area in plan view, and a plug directly connected only to the non-conductive area in the base layer is included in the plug arrangement area.

In each of the configurations, a dummy plug exists. With the configurations, the fabricating method of applying the material of the plug first on the entire face and simultaneously forming the plug and the dummy plug by using a photolithographic pattern covering the plug arrangement area including a portion in which no plug is necessary can be employed. Thus, fabrication is facilitated and the device can be fabricated with high accuracy. Because of the presence of the dummy plug, the top face can be easily planarized in a post process.

In order to achieve the object, according to another aspect of the invention, a semiconductor device includes: a base layer having a main surface; a plurality of wiring swellings formed so as to be linearly swollen on the main surface; and a plurality of plugs made of a conductive material formed so as to bury a part of a recess in plan view, the recess formed on the main surface by being sandwiched by the wiring swellings. The wiring swelling includes a wiring layer, a wiring layer top face protective layer formed so as to cover the top face of the wiring layer, and a side wall spacer covering a side face of the wiring layer and a side face of the wiring layer top face protective layer. A plug arrangement area in which at least three plugs are arranged in a direction intersecting the wiring swelling is provided. The level of the top face of the wiring swelling in the portion sandwiched by plugs in the plug arrangement area is higher than that of the top face of the other portion of the wiring swelling. With the configuration, a fabrication method of forming a plug first and forming the insulating interlayer next can be employed. Thus, a problem of short circuit between plugs caused by a cavity conventionally created in the insulating interlayer can be solved. Since the number of times the side wall spacer is subjected to etching decreases, insulation of the wiring layer by the side wall spacer can be performed more reliably.

In the invention, preferably, a plug arrangement area in which at least four plugs are arranged in the direction intersecting the wiring swelling is provided. The base layer is a semiconductor substrate partly having an isolated insulating film in the main surface, and a plug directly connected only to the isolated insulating film in the base layer is included in the plug arrangement area. Alternately, in the invention, preferably, a plug arrangement area in which at least four plugs are arranged in the direction intersecting the wiring swelling is provided. The wiring swelling includes an insulating interlayer under the wiring layer, the base layer includes a conductive area and a non-conductive area in plan view, and a plug directly connected only to the non-conductive area in the base layer is included in the plug arrangement area.

In each of the configurations, a dummy plug exists. With the configurations, the fabricating method of applying the material of the plug first on the entire face and simultaneously forming the plug and the dummy plug by using a photolithographic pattern covering the plug arrangement area including a portion in which no plug is necessary can be employed. Thus, fabrication is facilitated and the device can be fabricated with high accuracy. Because of the presence of the dummy plug, the top face can be easily planarized in a post process.

In order to achieve the object, according to the invention, a method of fabricating a semiconductor device includes: a wiring swelling forming step of forming a plurality of wiring swellings on a base layer having a main surface so as to be linearly swollen on the main surface; a conducting material filling step of filling a recess created in the main surface by being sandwiched by the wiring swellings with a conductive material so as to linearly bury the recess; and a plug forming step of removing the conductive material except for an area which becomes a plug. By adopting the method, since a plug is formed first and then the insulating interlayer is formed, a problem of short circuit between plugs caused by a cavity conventionally created in the insulating interlayer can be solved. Since the number of times the side wall spacer is subjected to etching decreases, insulation of the wiring layer by the side wall spacer can be performed more reliably.

In the invention, preferably, the plug forming step includes: a resist applying step of forming a resist film on the entire top face of the wiring swelling and the conductive material; a resist pattern forming step of forming a resist pattern by removing an unnecessary portion from the resist film by a mask pattern covering a desired area in which a plug is to be formed; and a conductive material removing step of removing the conductive material by using the resist pattern as a mask. By employing the method, a plug can be formed easily with high accuracy. A mask pattern obtained by reversing the conventional mask pattern can be used, so that acquisition of the mask pattern is simplified.

In the invention, preferably, the mask pattern has a pattern shape covering at least three desired areas arranged in a direction intersecting the wiring swelling. By adopting the method, the mask pattern can be simplified, and a plug can be formed easily with high accuracy.

In the invention, preferably, the mask pattern has a pattern shape covering the four or more desired areas arranged in the direction intersecting the wiring swelling. By adopting the method, the mask pattern can be simplified, and a plug can be formed more easily with high accuracy. Since a plug and a dummy plug are simultaneously formed, the flatness of the surface when an insulating interlayer or the like is formed can be improved.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view in a first process of a method of fabricating a semiconductor device according to a first embodiment of the invention;

FIG. 2 is a cross section taken along line II-II of FIG. 1;

FIG. 3 is a cross section in a second process of the method of fabricating the semiconductor device according to the first embodiment of the invention;

FIG. 4 is a cross section in a third process of the method of fabricating the semiconductor device according to the first embodiment of the invention;

FIG. 5 is a cross section in a fourth process of the method of fabricating the semiconductor device according to the first embodiment of the invention;

FIG. 6 is a cross section in a fifth process of the method of fabricating the semiconductor device according to the first embodiment of the invention;

FIG. 7 is a plan view in the fifth process of the method of fabricating the semiconductor device according to the first embodiment of the invention;

FIG. 8 is a plan view in a sixth process of the method of fabricating the semiconductor device according to the first embodiment of the invention;

FIG. 9 is a plan view in a seventh process of the method of fabricating the semiconductor device according to the first embodiment of the invention;

FIG. 10 is a cross section taken along line X-X of FIG. 9;

FIG. 11 is a cross section in an eighth process of the method of fabricating the semiconductor device according to the first embodiment of the invention;

FIG. 12 is a cross section in a ninth process of the method of fabricating the semiconductor device according to the first embodiment of the invention;

FIG. 13 is a plan view in a sixth process of a method of fabricating a semiconductor device according to a second embodiment of the invention;

FIG. 14 is a plan view in a seventh process of the method of fabricating the semiconductor device according to the second embodiment of the invention;

FIG. 15 is a cross section taken along line XV-XV of FIG. 14;

FIG. 16 is a plan view in an eighth process of the method of fabricating the semiconductor device according to the second embodiment of the invention;

FIG. 17 is a cross section taken along line XVII-XVII of FIG. 16;

FIG. 18 is a cross section in a ninth process of the method of fabricating the semiconductor device according to the second embodiment of the invention;

FIG. 19 is a plan view in a sixth process of a method of fabricating a semiconductor device according to a third embodiment of the invention;

FIG. 20 is a plan view in a seventh process of the method of fabricating the semiconductor device according to a third embodiment of the invention;

FIG. 21 is a cross section taken along line XXI-XXI of FIG. 20;

FIG. 22 is a plan view in an eighth process of the method of fabricating the semiconductor device according to the third embodiment of the invention;

FIG. 23 is a cross section taken along line XXIII-XXIII of FIG. 22;

FIG. 24 is a cross section in a ninth process of the method of fabricating the semiconductor device according to the third embodiment of the invention;

FIG. 25 is a cross section in a first process of the method of fabricating the semiconductor device according to a fourth embodiment of the invention;

FIG. 26 is a cross section in a second process of the method of fabricating the semiconductor device according to the fourth embodiment of the invention;

FIG. 27 is a cross section in a third process of the method of fabricating the semiconductor device according to the fourth embodiment of the invention;

FIG. 28 is a cross section in a fourth process of the method of fabricating the semiconductor device according to the fourth embodiment of the invention;

FIG. 29 is a cross section in a fifth process of the method of fabricating the semiconductor device according to the fourth embodiment of the invention;

FIG. 30 is a cross section in a sixth process of the method of fabricating the semiconductor device according to the fourth embodiment of the invention;

FIG. 31 is a cross section in a seventh process of the method of fabricating the semiconductor device according to the fourth embodiment of the invention;

FIG. 32 is a cross section in an eighth process of the method of fabricating the semiconductor device according to the fourth embodiment of the invention;

FIG. 33 is a cross section in a ninth process of the method of fabricating the semiconductor device according to the fourth embodiment of the invention;

FIG. 34 is a plan view in a first process of a method of fabricating a semiconductor device according to a conventional technique;

FIG. 35 is a cross section taken along line XXXV-XXXV of FIG. 34;

FIG. 36 is a cross section in a second process of the method of fabricating the semiconductor device according to the conventional technique;

FIG. 37 is a cross section in a third process of the method of fabricating the semiconductor device according to the conventional technique;

FIG. 38 is a plan view in a fourth process of the method of fabricating the semiconductor device according to the conventional technique;

FIG. 39 is a plan view in a fifth process of the method of fabricating the semiconductor device according to the conventional technique;

FIG. 40 is a cross section taken along line XL-XL of FIG. 39;

FIG. 41 is a cross section in a sixth process of the method of fabricating the semiconductor device according to the conventional technique;

FIG. 42 is a cross section in a seventh process of the method of fabricating the semiconductor device according to the conventional technique;

FIG. 43 is a plan view of the structure of FIG. 42;

FIG. 44 is a cross section in an eighth process of the method of fabricating the semiconductor device according to the conventional technique;

FIG. 45 is a cross section in a ninth process of the method of fabricating the semiconductor device according to the conventional technique; and

FIG. 46 is an explanatory diagram showing problems of the semiconductor device according to the conventional technique.

### DESCRIPTION OF THE PREFERRED EMBODIMENTS

First Embodiment

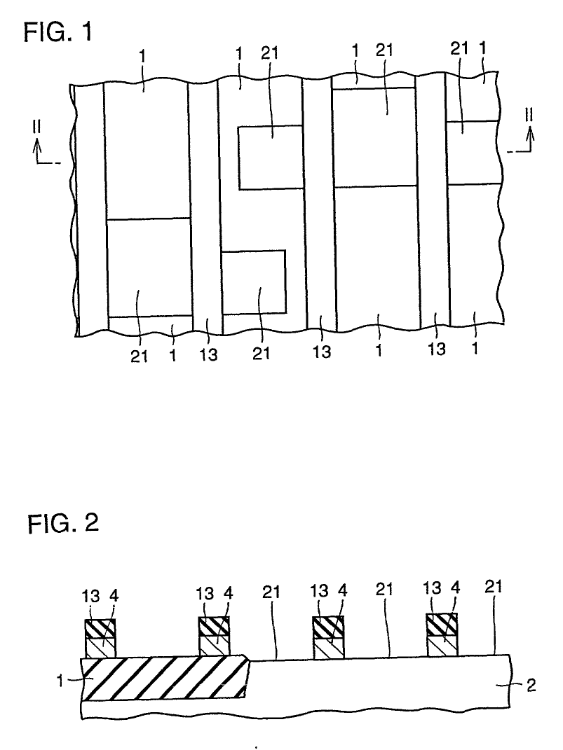

Referring to FIGS. 1 to 12, a method of fabricating a semiconductor device according to a first embodiment of the invention will be described.

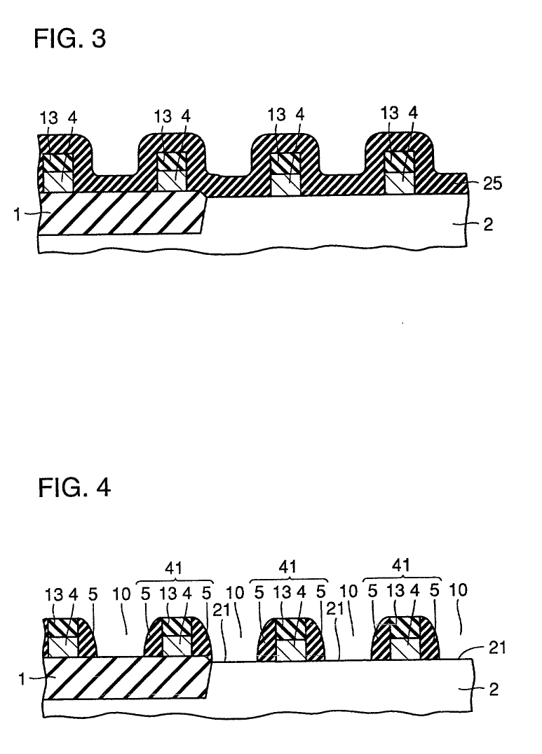

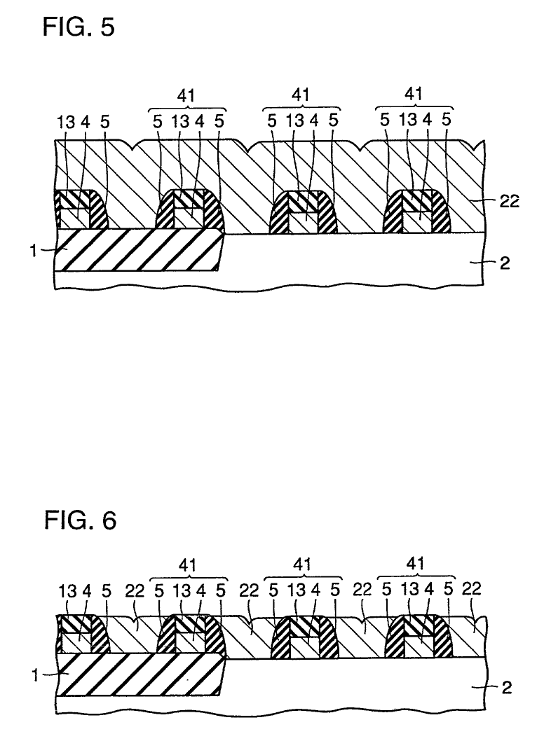

By a known technique, isolated insulating film 1 is formed in the surface of semiconductor substrate 2 except for active areas 21. On the top face of semiconductor substrate 2, wiring layer 4 covered with an on-wiring stopper film 13 is formed by a known technique. The on-wiring stopper film 13 has to be an insulating film having a sufficiently low selectivity in CMP or etching as compared with a conductive layer 22 (refer to FIG. 5) to be formed in a later process, that is, having an etching rate sufficiently lower than that of conductive layer 22. As on-wiring stopper film 13, for example, a silicon nitride film can be used. In such a manner, the structure shown in FIGS. 1 and 2 is obtained. As shown in FIG. 3, by CVD or the like, nitride film 25 is formed on the top face so as to cover wiring layer 4 and on-wiring insulating film 3.

As shown in FIG. 4, the entire face is subjected to anisotropic etching to remove nitride film 25 on the bottom of the recesses of FIG. 3 and active area 21 is exposed, thereby forming contact hole 10. Since contact holes 10 are formed in a self aligned manner, the holes are naturally formed without high accuracy position control. On the inside of connection hole 10, by making a part of nitride film 25 remain, side wall spacer 5 is formed. Side wall spacer 5 has a shape of, not a simple vertical wall, but a shape having a slope toward the bottom of contact hole 10.

The linearly swollen portion formed as described above including wiring layer 4, on-wiring stopper film 13, and side wall spacer 5 will be called a “wiring swelling” 41 hereinbelow.

As shown in FIG. 5, conductive layer 22 is formed so as to cover the entire face by CVD or the like. Conductive layer 22 is a layer which will become as plug 11 (refer to FIGS. 10 to 12) and is made of a material such as polysilicon or amorphous silicon.

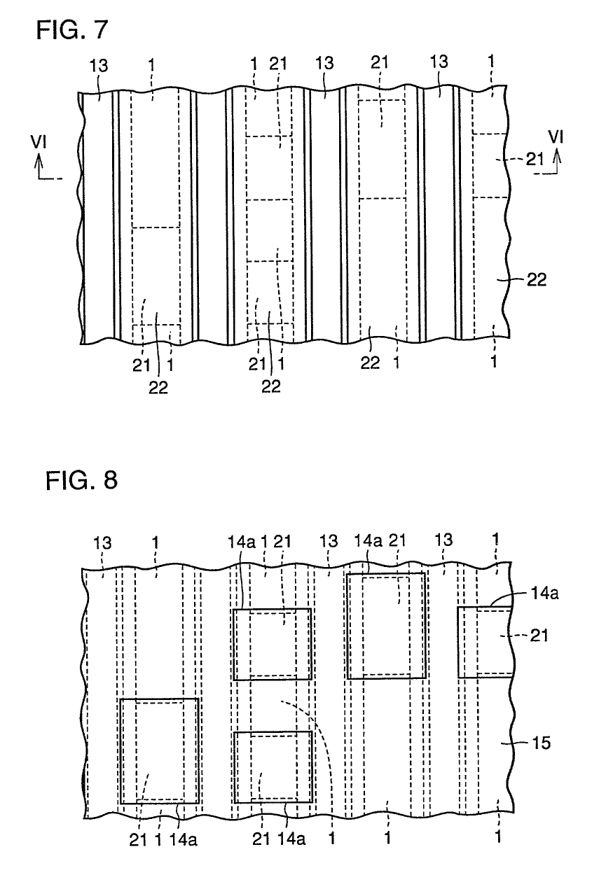

As shown in FIG. 6, on-wiring stopper film 13 is used as a stopper, and the entire face is subjected to CMP or dry etching. The process is stopped when the top face of on-wiring stopper film 13 is exposed. As a result, the top face of on-wiring stopper film 13 and that of the remaining portion of conductive layer 22 become almost flat and flush with each other. FIG. 7 is a plan view showing this state. FIG. 6 is a cross section taken along line VI-VI of FIG. 7.

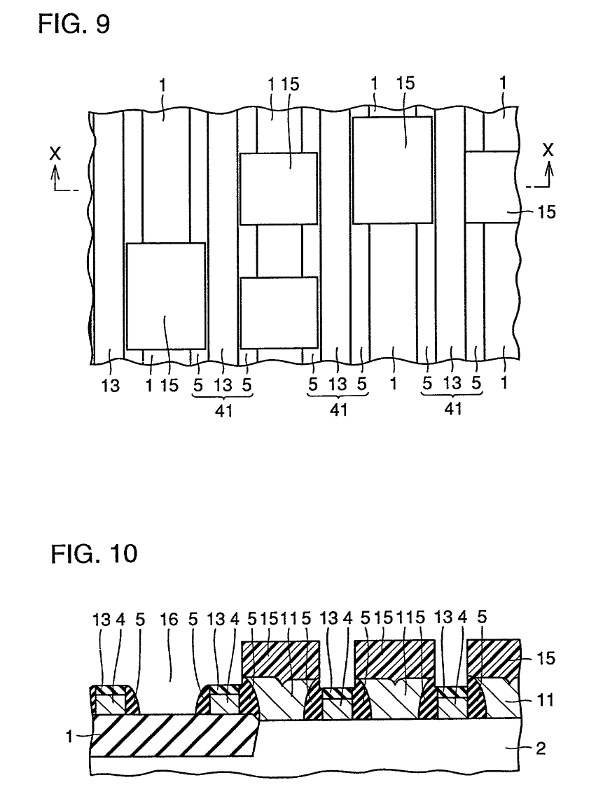

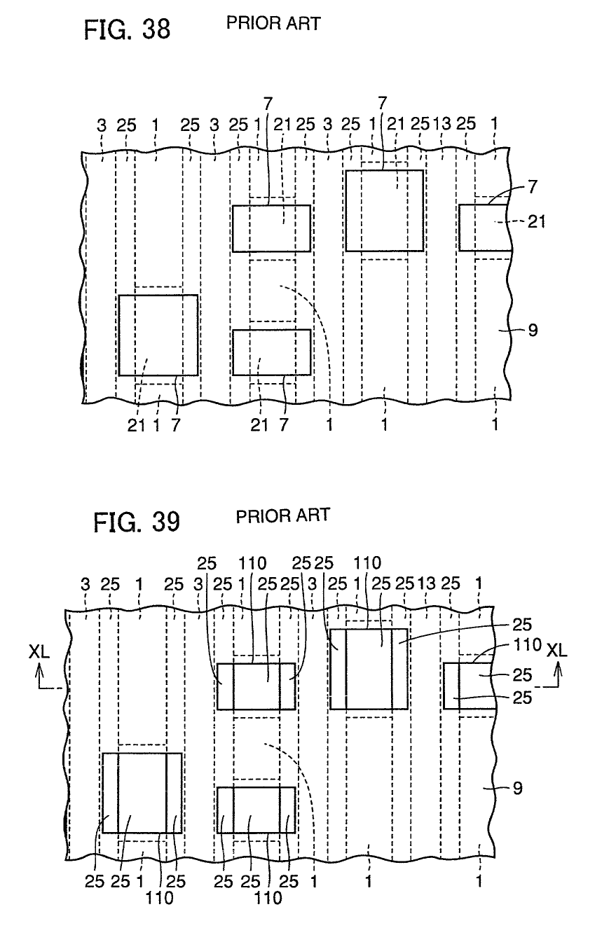

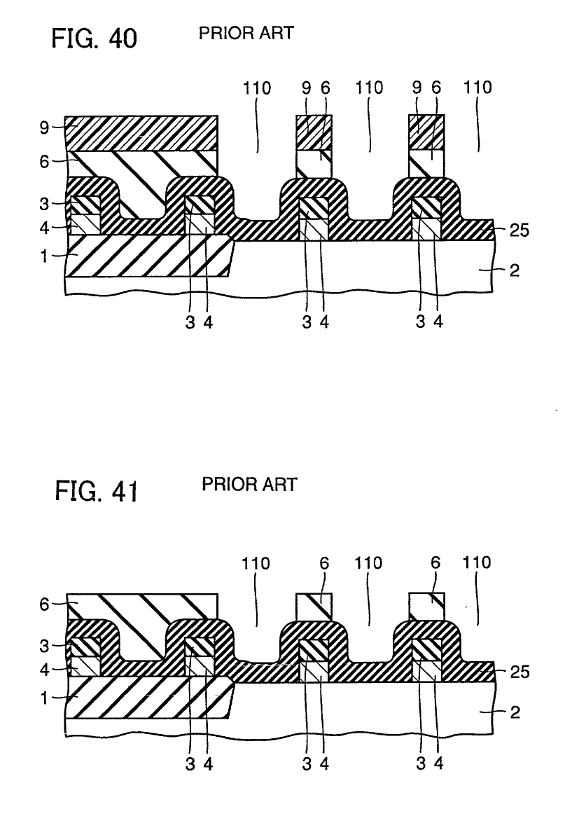

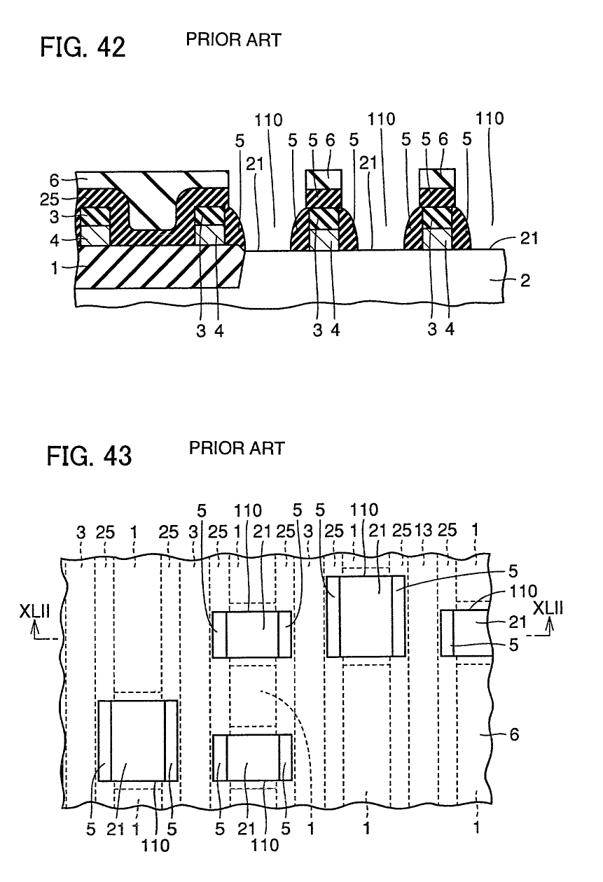

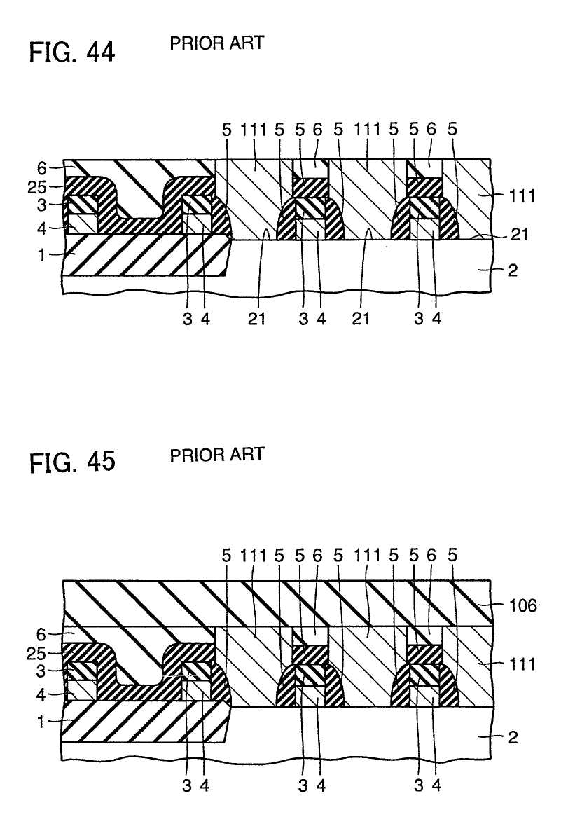

As shown in FIG. 8, a resist film 15 is formed on the entire top face. A photolithographic pattern 14a is overlaid on each active area 21 and exposure is performed. Photolithographic pattern 14a used here is similar to photolithographic pattern 7 (refer to FIG. 38) used in the conventional technique but is reversed. Consequently, with conventional photolithographic pattern 7, resist film 15 is removed only in the portion where a connection hole is desired to be formed, and the resist film 15 remains on the other portion. In the embodiment, on the contrary, resist film 15 remains only in the portion where a connection hole is desired to be formed, and the resist film 15 on the other portion is removed. Further, while using resist film 15 as a mask, dry etching is performed, and conductive layer 22 is removed in a plug-unnecessary portion 16. Only the portion under resist film 15 of conductive layer 22 remains and serves as plug 11. FIG. 9 is a plan view showing the state. FIG. 10 is a cross section taken along line X-X of FIG. 9. On-wiring stopper film 13, side wall spacer 5, and isolated insulating film 1 around the plug-unnecessary portion 16 are slightly removed from their surfaces. As described above, the material has an etching rate sufficiently lower than that of conductive layer 22, so that its removal amount does not become an issue. By setting etching time to be slightly long, conductive layer 22 can be therefore removed without being left on the bottom of plug-unnecessary portion 16. It is sufficient to form on-wiring stopper film 13 thickly so as not to be eliminated even by planarization of the top face of conductive layer 22 (refer to FIG. 6) and removal of conductive layer 22 in plug unnecessary portions 16 (refer to FIG. 10).

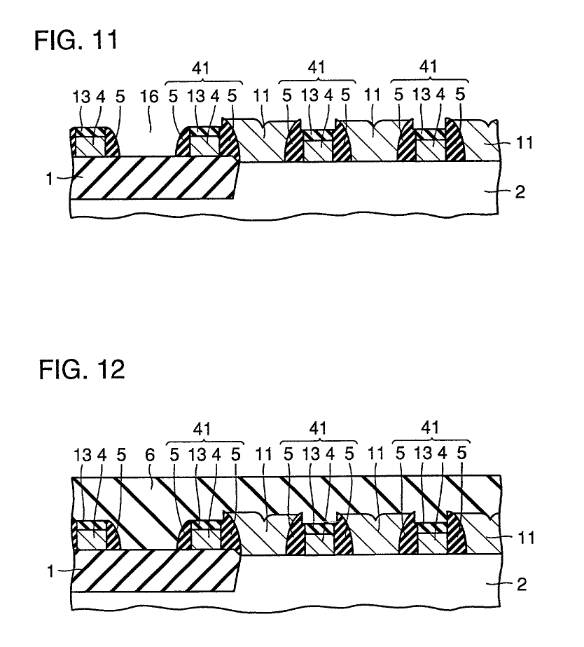

As shown in FIG. 11, resist film 15 is removed. As shown in FIG. 12, insulating interlayer 6 is formed so as to cover the entire face by CVD or the like. The top face of insulating interlayer 6 is planarized by CMP, etch back, or the like. In such a manner, the next wiring layer can be formed on the top face of insulating interlayer 6.

By repeating such a process, a semiconductor device in which a plurality of wiring layers are stacked and are connected to each other via plugs in the vertical direction is obtained.

The semiconductor device in the embodiment has a structure as shown in FIG. 12. Specifically, when the state after insulating interlayer 6 is removed is assumed, wiring swellings 41 extend linearly on the surface of semiconductor substrate 2 and a recess is created in the main surface by being sandwiched by wiring swellings 41. In plan view, plural plugs 11 are formed by a conductive material so as to bury a part of the recess. The top face of wiring swelling 41 and that of plug 11 are almost flush with each other with reference to the main surface as a reference. In practice, the upper side of the structure is covered with insulating interlayer 6.

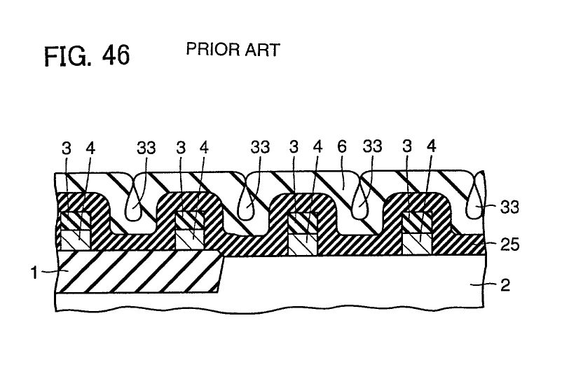

By forming insulating interlayer 6 after forming side wall spacer 5 having a slope, the burying operation with insulating interlayer 6 is facilitated, and cavities 33 (refer to FIG. 46) or the like which are generated in the case where the burying property is insufficient do not occur.

Since plugs 11 are formed before insulating interlayer 6, even if the burying property of insulating interlayer 6 is poor and cavities 33 or the like are generated, a problem such as short-circuiting by the material of plug 11 does not occur.

Further, since connection holes for plugs 11 are formed in a self-aligned manner before insulating interlayer 6, the number of times side wall spacer 5 is subjected to etching decreases, so that the reduction amount of side wall spacer 5 is decreased. Wiring layer 4 and plug 11 are insulated from each other by side wall spacer 5 with reliability.

Since the burying property and insulating property are determined only by variations in film thickness of side wall spacer 5 without being influenced by variations in film thickness of on-wiring stopper film 13 and insulating interlayer 6, stable mass production can be realized.

Further, in the conventional technique, two insulating interlayers 6 and 106 are necessary as shown in FIG. 45, so that the device as a whole is thick. In contrast, in the embodiment, only insulating interlayer 6 is sufficient, so that the thickness as a whole can be reduced. Accordingly, the fabricating process can be also simplified.

Second Embodiment

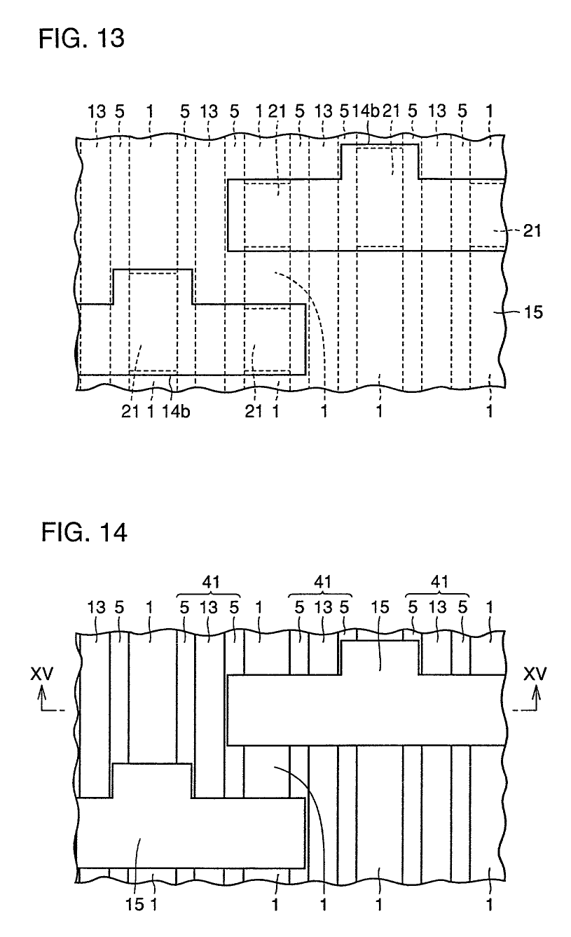

Referring to FIGS. 13 to 18, the method of fabricating a semiconductor device according to a second embodiment of the invention will be described.

In the first embodiment, as a photolithographic pattern for leaving the portions corresponding to plugs, photolithographic pattern 14a (refer to FIG. 8) having the shape corresponding to each of plugs is adopted. In the second embodiment, as shown in FIG. 13, a photolithographic pattern 14b having a shape covering a plurality of neighboring plugs is used. A collection of a plurality of plugs arranged close to each other will be called a “plug arrangement area” hereinbelow. Photolithographic pattern 14b having a shape in the embodiment covers one plug arrangement area. In the example, a collection of three plugs formed in an active area 8 which is continuous before formation of wiring layer 4 and the like, that is, a collection of three plugs for two transistors commonly using one source area from both sides is called a plug arrangement area. One plug arrangement area is not limited to a continuous active area. One plug arrangement area includes three plugs or may include the other number of plugs.

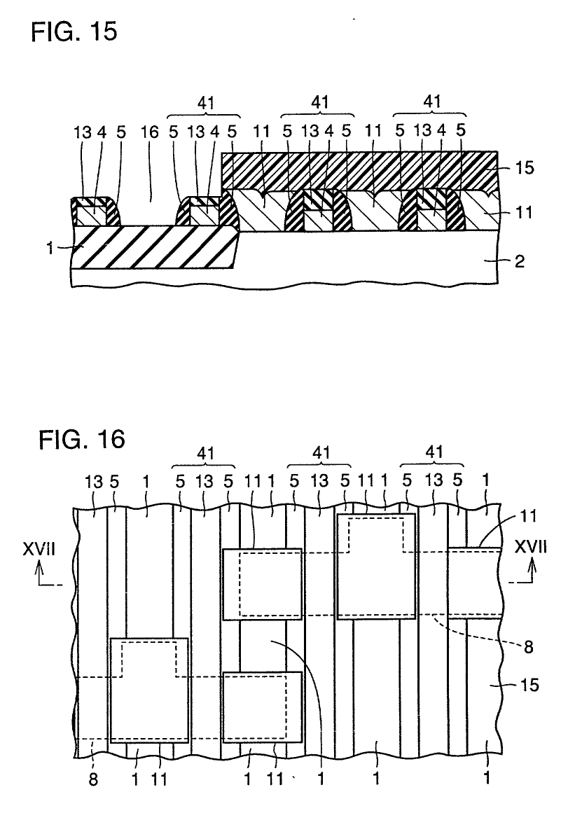

FIG. 13 corresponds to the stage of FIG. 8 in the first embodiment. The process up to here is similar to that in the first embodiment. Specifically, at the stage of FIG. 13, the entire top face is covered with resist film 15. Dry etching is performed by using resist film 15 remained as a result of exposure with photolithographic pattern 14b, as a mask to remove conductive layer 22 in plug-unnecessary portion 16. FIG. 14 is a plan view showing the state. FIG. 15 is a cross section taken along line XV-XV of FIG. 14. Although on-wiring stopper film 13, side wall spacer 5, and isolated insulating film 1 around plug unnecessary portion 16 are slightly removed from their top faces, as described above, the material has the etching rate sufficiently low as compared with conductive layer 22, so that the removal amount does not become an issue. By setting etching time to be slightly long, conductive layer 22 can be removed without being left on the bottom of plug-unnecessary portion 16. It is sufficient to form on-wiring stopper film 13 thickly so as not to be eliminated even by planarization of the top face of conductive layer 22 and removal of conductive layer 22 in plug-unnecessary portions 16.

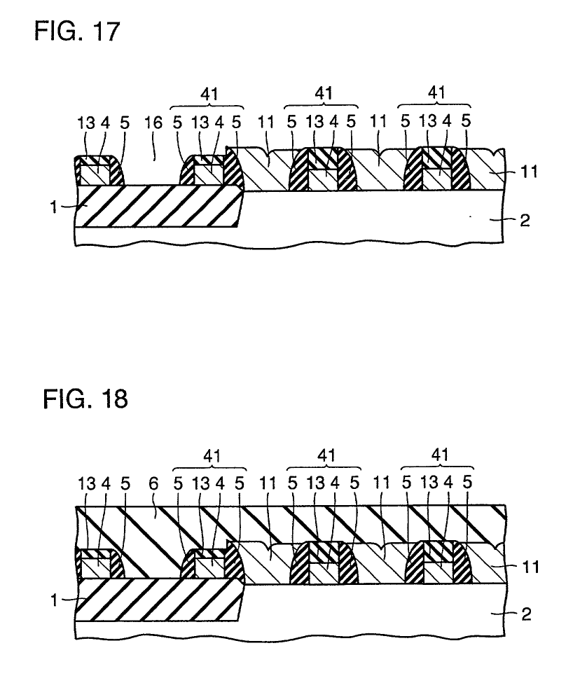

As shown in FIGS. 16 and 17, resist film 15 is removed. In this case, in each plug arrangement area, wiring swelling 41 in the portion sandwiched by plugs 11 is covered with resist film 15 formed by using photolithographic pattern 14b. The other portion in the linearly extended wiring swelling 41 is not covered with resist film 15, so that the level of the top face of wiring swelling 41 in the portion sandwiched by plugs 11 is higher than that the top face of wiring swelling 41 in the other portion.

As shown in FIG. 18, insulating interlayer 6 is formed so as to cover the whole face by CVD or the like. The following process is similar to that described in the first embodiment.

As described above, by using the photolithographic pattern having a shape covering a plug arrangement area, the pattern of resist film can be simplified, and the device can be easily formed with high accuracy.

Third Embodiment

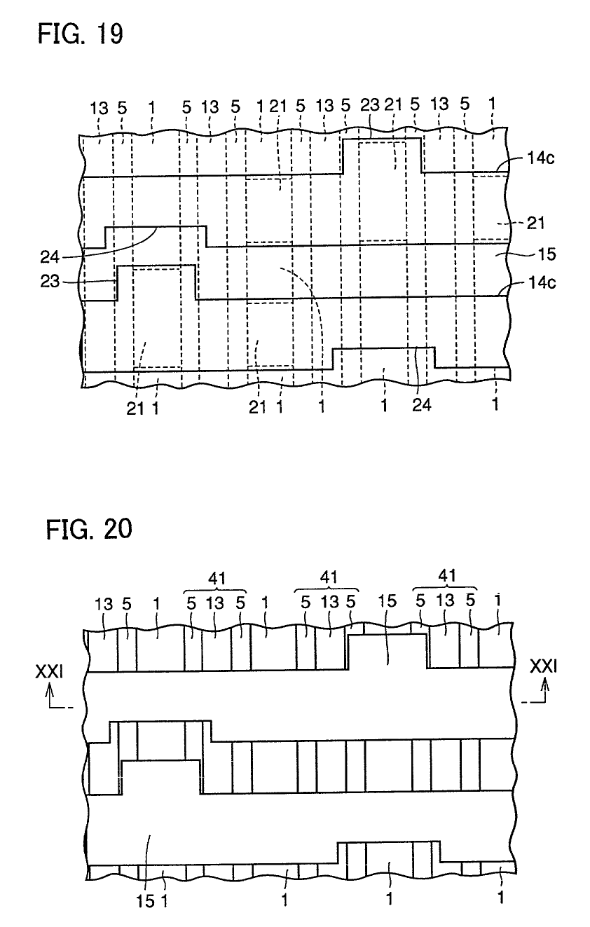

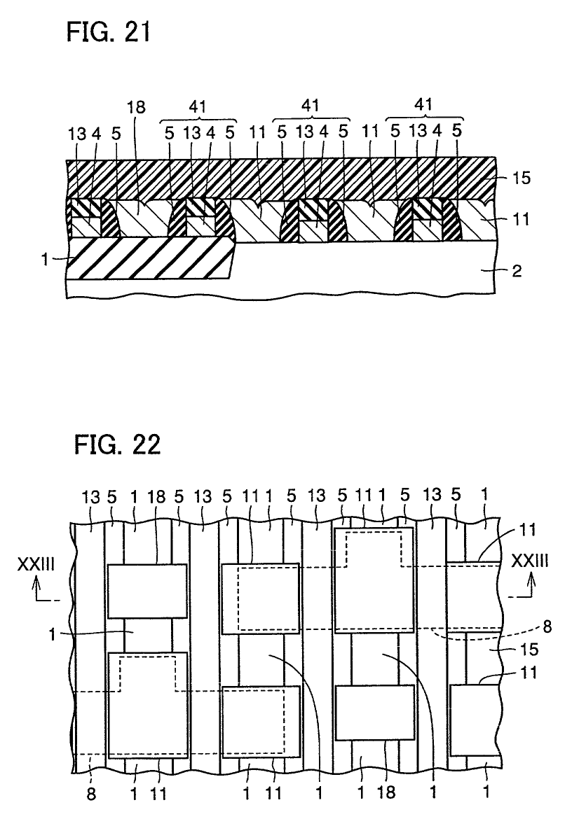

Referring to FIGS. 19 to 24, a method of fabricating a semiconductor device according to a third embodiment of the invention will be described. In the second embodiment, one plug arrangement area is constructed by a collection of three plugs formed in a single active area 8, that is, a collection of three plugs for two transistors commonly using one source area from both sides. In the third embodiment, as shown in FIG. 19, regardless of whether the active area is continuous or not, an area including plugs arranged on a straight line perpendicular to the extending direction of wiring layer 4 as one plug arrangement area. A photolithographic pattern 14c covering all the plugs on the straight line is therefore adopted. In this case, in order to avoid undesired conduction between a plug arrangement area and the other neighboring plug arrangement area, in the plug arrangement area, preferably, a notch 24 is formed in a portion close to a projection 23 of the neighboring plug arrangement area so as to keep a certain distance between the areas. By using resist film 15 remained after performing exposure with photolithographic pattern 14c, dry etching is performed. Consequently, conductive layer 22 in the portion which is not covered with resist film 15 is removed. FIG. 20 is a plan view showing the state. FIG. 21 is a cross section taken along line XXI-XXI of FIG. 20. On-wiring stopper film 13, side wall spacer 5, and isolated insulating film 1 in the portion which is not covered with resist film 15 are slightly removed from their top surfaces in a manner similar to the second embodiment. In the third embodiment, there is a portion in plug unnecessary portion, which is covered with resist film, and a plug is formed also in such a portion. The plug has a shape similar to that of plug 11 but is a dummy plug 18 having no function of the plug. However, since the lower end of dummy plug 18 is connected only to isolated insulating film 1, it is not electrically connected to somewhere. Consequently, even when dummy plug 18 exists, there is no harm.

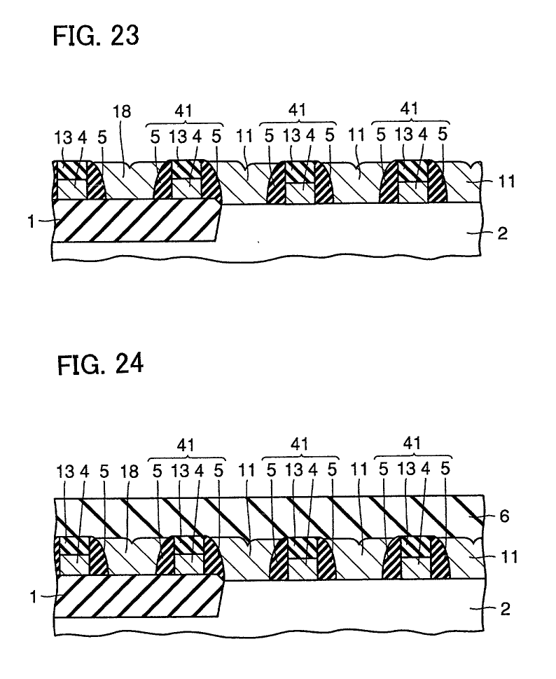

As shown in FIG. 22 and 23, resist film 15 is removed. FIG. 23 is a cross section taken along line XXIII-XXIII of FIG. 22. A step generated in the top face of wiring swelling 41 is similar to that described in the second embodiment. As shown in FIG. 24, insulating interlayer 6 is formed so as to cover the entire surface by CVD or the like. The following process is similar to that in the first embodiment. In this case, also in the final structure, dummy plug 18 remains as a plug-shaped portion directly connected only to isolated insulating film 1.

As described above, by using the photolithographic pattern having a shape covering all plugs arranged in a straight line as a plug arrangement area, the pattern of a resist film can be further simplified and can be easily formed with high accuracy. In the embodiment, although dummy plug 18 is formed also in a portion where no plug 11 is necessary, dummy plug 18 of the same material and the same shape as plug 11 is formed so as to bury a portion where plug 11 is not inherently formed. Consequently, the flatness of the top face after formation of insulating interlayer 6 can be increased.

Fourth Embodiment

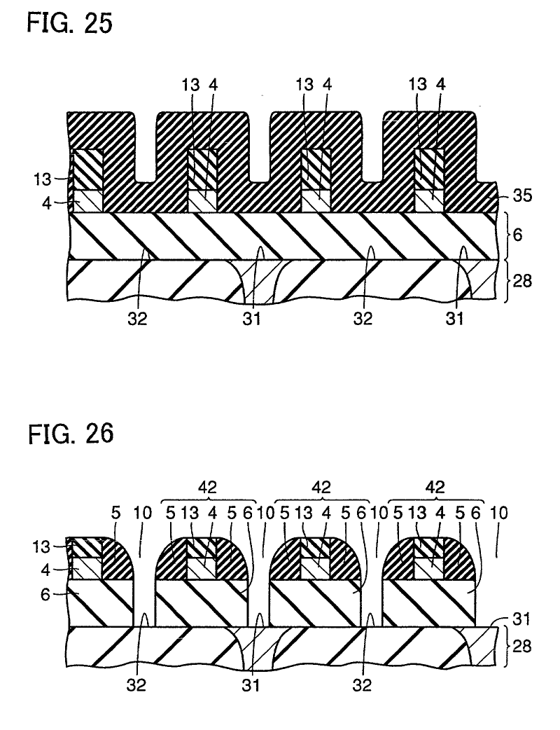

Referring to FIGS. 25 to 30, a method of fabricating a semiconductor device according to a fourth embodiment of the invention will be described.

In the first to third embodiments, the invention relates to examples characterized by the layer including plugs 11 directly connected to active area 21 of semiconductor substrate 2, As the fourth embodiment, the invention relates to an example characterized by a layer including plugs connected to a conductive area in the relatively next lower layer in a stacked structure of one or more layers on semiconductor substrate 2.

As shown in FIG. 25, the structure including wiring layer 4 is formed on a lower wiring layer 28 via insulating interlayer 6. Lower wiring layer 28 includes a conductive area 31 and a non-conductive area 32. Lower wiring layer 28 may be the layer formed in the first to third embodiments. In this case, conductive area 31 corresponds to plug 11. FIG. 25 is a cross section showing a stage corresponding to FIG. 3 of the first embodiment. Wiring layer 4 is formed on insulating interlayer 6 and is covered with on-wiring stopper film 13. On-wiring stopper film 13 is further covered with a nitride film 35. On-wiring stopper layer 13 is formed thicker as compared with FIG. 3 so that, since etching is performed longer to form a deeper connection hole 10 in the following process (refer to FIG. 26), wiring layer 4 is not exposed even by the etching.

As shown in FIG. 26, the entire face is subjected to anisotropic dry etching to form connection hole 10 reaching lower wiring layer 28. Connection holes 10 are formed in a self-aligned manner. A part of nitride film 35 remains and serves as side wall spacer 5. A portion including wiring layer 4, on-wiring stopper film 13, side wall spacer 5, and insulating interlayer 6, which is swollen linearly in the direction perpendicular to the drawing sheet of FIG. 26 is a wiring swelling 42.

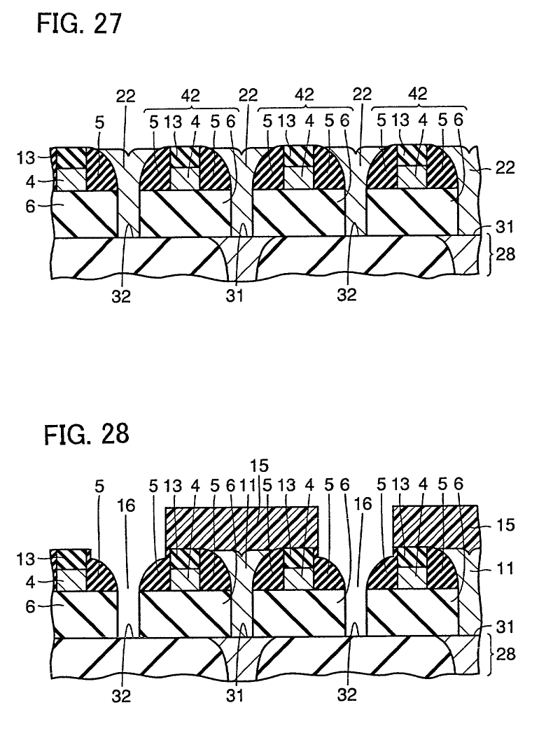

As shown in FIG. 27, conductive layer 22 is formed in a portion sandwiched by wiring swellings 42. The method of forming conductive layer 22 is the same as that described with reference to FIGS. 5 and 6 in the first embodiment. As a result, the top face of on-wiring stopper film 13 and that of the remaining portion of conductive layer 22 become almost flat and flush with each other.

In a manner similar to the first to third embodiments, after applying resist film 15 on the entire face, exposure is performed with a photolithographic pattern. As in the first embodiment, an example of using the photolithographic pattern covering each portion in which a plug is to be formed will be described. Therefore, resist film 15 only in the portion where a connection hole is desired to be formed remains, and resist film 15 in the other portion is removed. Further, while using resist film 15 as a mask, dry etching is performed to thereby eliminate conductive layer 22 in plug unnecessary portions 16. Only the portion under resist film 15 in conductive layer 22 remains and becomes plug 11.

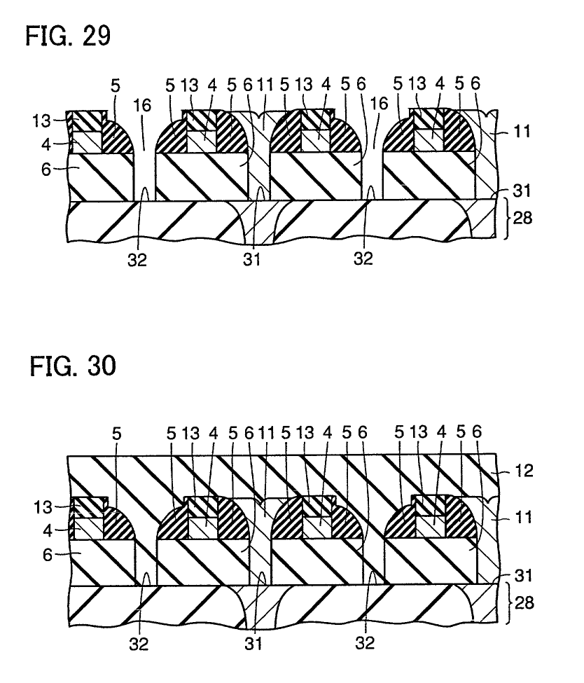

As shown in FIG. 29, resist film 15 is removed. As shown in FIG. 30, insulating interlayer 12 is formed so as to cover the whole face by CVD or the like. Insulating interlayer 12 is planarized by CMP, etch back, or the like. Consequently, the next wiring layer can be formed on insulating interlayer 12.

By repeating such a process, a semiconductor device in which a plurality of wiring layers are stacked and connected to each other via a plug in the vertical direction is obtained.

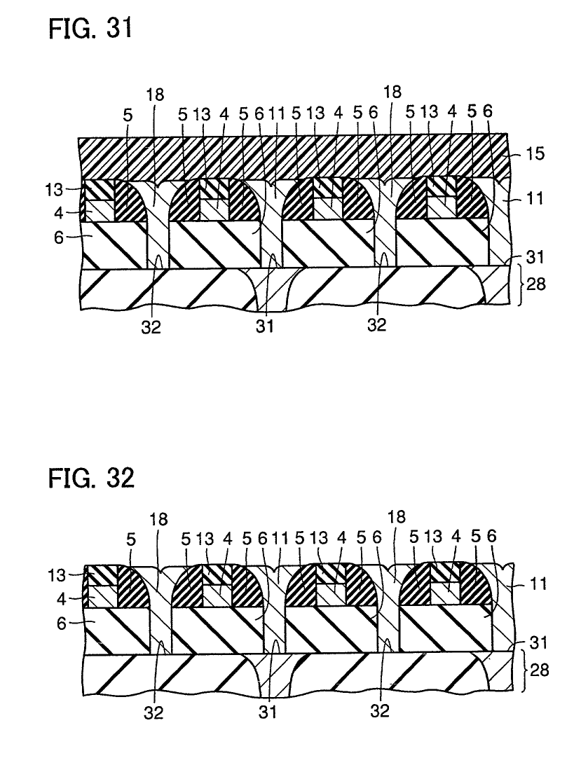

Referring to FIGS. 31 to 33, another example in the embodiment will be described. In the above-described example, the photolithographic pattern having the shape covering each portion where a plug is to be formed is used. As used in the third embodiment, a photolithographic pattern having a shape which extends linearly so as to cross a plurality of areas in which plugs are to be formed may be used. In this case, at a stage after dry etching is carried out by using resist film 15 as a mask, that is, a stage corresponding to FIG. 28, as shown in FIG. 31, not only plugs 11 inherently necessary but also dummy plug 18 are formed. Since the lower end of each dummy plug 18 is connected only to non-conductive area 32 in lower wiring layer 28, it is not electrically connected to somewhere and does not cause a problem even when it exists.

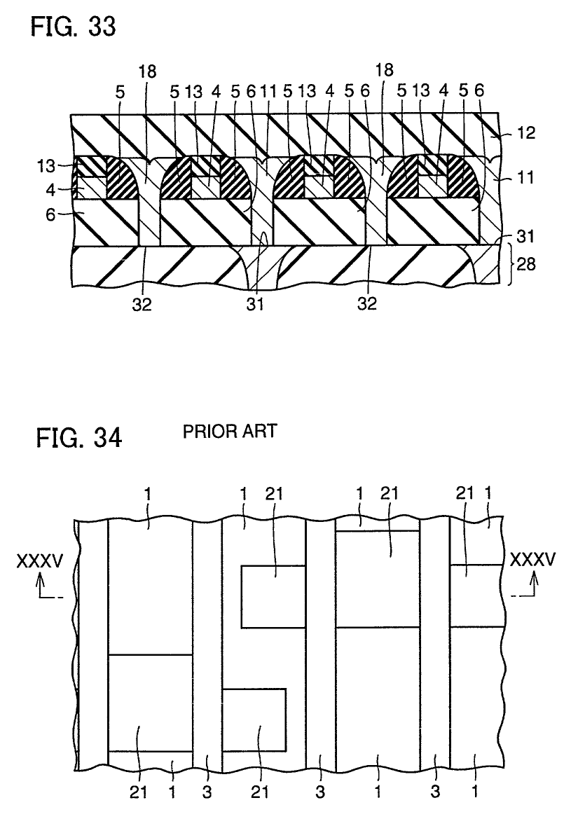

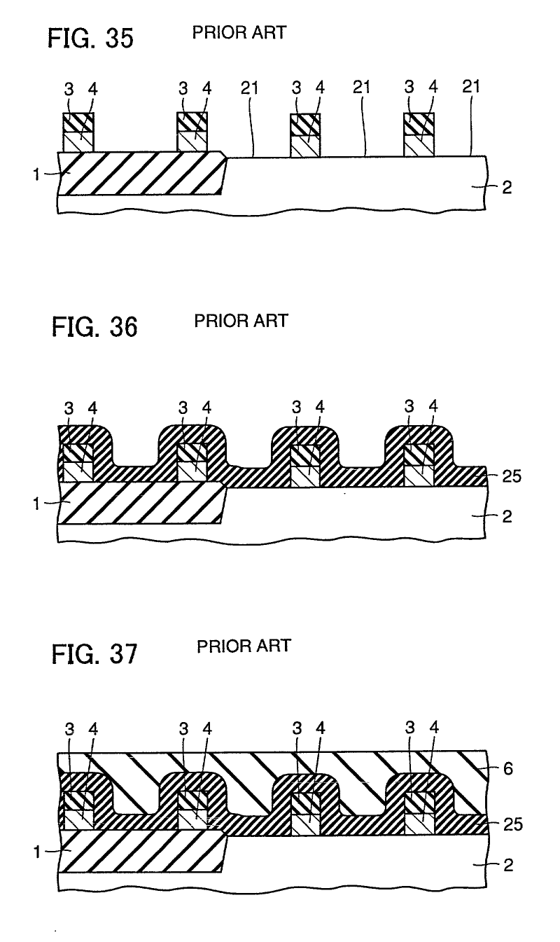

As shown in FIG. 32, resist film 15 is removed. As shown in FIG. 33, insulating interlayer 12 is formed so as to cover the entire surface by CVD or the like. The following process is similar to that in the first embodiment. In this case, also in a final product, dummy plug 18 remains as a plug-shaped portion directly connected only to non-conductive area 32 in lower wiring layer 28.

Although the structure of a memory cell of a DRAM (Dynamic Random Access Memory) has been shown as an example in each of the foregoing embodiments, the invention can be applied to other semiconductor devices each using a self-aligned structure, such as SRAM (Static Random Access Memory) and ROM (Read Only Memory). The invention may be applied to a circuit other than a memory cell.

According to the invention, since a fabricating method in which plugs are formed first and an insulating interlayer is formed next can be used, the problem of short-circuit between plugs caused by a cavity which is conventionally generated in the insulating interlayer can be solved. Since the number of times the side wall space is subjected to etching decreases, insulation of the wiring layer by the side wall spacer becomes more reliable. Further, the plugs have the height about the same as that of the wiring swelling, so that the thickness as a whole can be reduced.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device comprising:
a base layer having a main surface;
a plurality of wiring swellings formed so as to be linearly swollen on said main surface; and
a plurality of plugs made of a conductive material formed so as to bury a part of a recess in plan view, the recess formed on said main surface by being sandwiched by said wiring swellings,
said wiring swelling including a wiring layer, a wiring layer top face protective layer formed so as to cover the top face of the wiring layer, and a side wall spacer covering a side face of said wiring layer and a side face of said wiring layer top face protective layer, and
the level of the top face of said wiring swelling and that of the top face of said plug being almost the same with respect to said main surface as a reference.

2. The semiconductor device according to claim 1, further comprising a plug arrangement area in which at least three plugs are arranged in the direction intersecting said wiring swelling,
wherein in said plug arrangement area, the level of the top face of said wiring swelling in a portion sandwiched by said plugs is higher than that of the top face of the other portion in said wiring swelling.

3. The semiconductor device according to claim 2, further comprising a plug arrangement area in which at least four plugs are arranged in the direction intersecting said wiring swelling,
wherein said base layer is a semiconductor substrate partly having an isolated insulating film in said main surface, and
a plug directly connected only to said isolated insulating film in said base layer is included in said plug arrangement area.

4. The semiconductor device according to claim 2, further comprising a plug arrangement area in which at least four plugs are arranged in the direction intersecting said wiring swelling,
wherein said wiring swelling includes an insulating interlayer under said wiring layer,
said base layer includes a conductive area and a non-conductive area in plan view, and
a plug directly connected only to said non-conductive area in said base layer is included in said plug arrangement area.

5. A semiconductor device comprising:
a base layer having a main surface;
a plurality of wiring swellings formed so as to be linearly swollen on said main surface; and
a plurality of plugs made of a conductive material formed so as to bury a part of a recess in plan view, the recess formed on said main surface by being sandwiched by said wiring swellings,
said wiring swelling including a wiring layer, a wiring layer top face protective layer formed so as to cover the top face of the wiring layer, and a side wall spacer covering a side face of said wiring layer and a side face of said wiring layer top face protective layer,
a plug arrangement area being provided in which at least three plugs are arranged in a direction intersecting said wiring swelling, and
the level of the top face of said wiring swelling in the portion sandwiched by plugs in said plug arrangement area being higher than that of the top face of the other portion of said wiring swelling.

6. The semiconductor device according to claim 5, further comprising a plug arrangement area in which at least four plugs are arranged in the direction intersecting said wiring swelling,
wherein said base layer is a semiconductor substrate partly having an isolated insulating film in said main surface, and
a plug directly connected only to said isolated insulating film in said base layer is included in said plug arrangement area.

7. The semiconductor device according to claim 5, further comprising a plug arrangement area in which at least four plugs are arranged in the direction intersecting said wiring swelling,
wherein said wiring swelling includes an insulating interlayer under said wiring layer,
said base layer includes a conductive area and a non-conductive area in plan view, and
a plug directly connected only to said non-conductive area in said base layer is included in said plug arrangement area.

8. A method of fabricating a semiconductor device, comprising:
a wiring swelling forming step of forming a plurality of wiring swellings on a base layer having a main surface so as to be linearly swollen on said main surface;
a conducting material filling step of filling a recess created in said main surface by being sandwiched by said wiring swellings with a conductive material so as to linearly bury the recess; and
a plug forming step of removing said conductive material except for an area which becomes a plug.

9. The method of fabricating a semiconductor device according to claim 8, wherein
said plug forming step includes:
a resist applying step of forming a resist film on the entire top face of said wiring swelling and said conductive material;
a resist pattern forming step of forming a resist pattern by removing an unnecessary portion from said resist film by a mask pattern covering a desired area in which a plug is to be formed; and
a conductive material removing step of removing said conductive material by using said resist pattern as a mask.

10. The method of fabricating a semiconductor device according to claim 9, wherein said mask pattern has a pattern shape covering at least three desired areas arranged in a direction intersecting said wiring swelling.

11. The method of fabricating a semiconductor device according to claim 10, wherein said mask pattern has a pattern shape covering said four or more desired areas arranged in the direction intersecting said wiring swelling.
